(19) United States
(12) Patent Application Publication
(10) Pub. No.: US 2026/0304885 A1
(43) Pub. Date: Oct. 1, 2026

(54) HIGH-ELECTRON-MOBILITY TRANSISTORS INCLUDING A TIERED FIELD PLATE

(71) Applicant: GlobalFoundries U.S. Inc., Malta, NY (US)

(72) Inventors: Brett Cucci, Colchester, VT (US); Zhong Xiang He, Essex Junction, VT (US); Mark Levy, Williston, VT (US)

(21) Appl. No.: 19/095,291

(22) Filed: Mar. 31, 2025

(51) Int. Cl. H10D 64/00; H10D 30/01; H10D 30/47; H10D 62/85

(52) U.S. Cl. CPC H10D 64/112; H10D 30/015; H10D 30/475; H10D 62/8503

(57) ABSTRACT

Structures for a high-electron-mobility transistor and methods of forming such structures. The structure comprises a field plate including a metal layer inside an opening in a dielectric layer. The metal layer includes a first section, a second section connected to the first section, a third section, and a fourth section connected to the third section. The first section is positioned on a portion of a first tiered sidewall between the second section and a top surface of the dielectric layer. The third section is positioned on a portion of a second tiered sidewall between the fourth section and the top surface of the dielectric layer. The first and third sections are coplanar, and the first and third sections have a first width. The second and fourth sections are coplanar, and the second and fourth sections have a second width.

### STATEMENT REGARDING FEDERALLY SPONSORED RESEARCH OR DEVELOPMENT

This invention was made with government support under HQ0727790700 awarded by the Defense Microelectronics Activity. The government has certain rights in the invention.

### BACKGROUND

The disclosure relates to semiconductor device fabrication and integrated circuits and, more specifically, to structures for a high-electron-mobility transistor and methods of forming such structures.

Compound semiconductors are characterized by advantageous material properties, such as a carrier mobility that is higher than the carrier mobility of silicon and a wider band gap than silicon, that can be exploited to fabricate device structures. Compound semiconductor materials may include, for example, Group III elements (e.g., aluminum, gallium, and/or indium) and Group V elements (e.g., nitrogen, phosphorus, arsenic, and/or antimony) combined with the Group III elements.

High-electron-mobility transistors based on compound semiconductors can be deployed in certain integrated circuit applications, such as high-voltage power electronics. A high-electron-mobility transistor may include a heterojunction between crystalline compound semiconductor materials having different band gaps, such as a heterojunction between binary gallium nitride and trinary aluminum-gallium nitride. During operation, a high concentration of high-mobility electrons accumulates near the heterojunction to supply a two-dimensional electron gas.

A conventional high-electron-mobility transistor is characterized by multiple terminals, namely a gate, a source ohmic contact, and a drain ohmic contact. The gate is used to control electron flow within the two-dimensional electron gas residing in a channel between the source ohmic contact and the drain ohmic contact. A metal field plate may be disposed between the gate and the drain ohmic contact. Limitations on the conformality of the metal deposition may create a sharp corner in the field plate and thereby create an unwanted leakage path.

Improved structures for a high-electron-mobility transistor and methods of forming such structures are needed.

### SUMMARY

In an embodiment of the invention, a structure comprises a dielectric layer including a top surface and an opening, and a field plate including a metal layer inside the opening in the dielectric layer. The opening including a first tiered sidewall and a second tiered sidewall opposite to the first tiered sidewall. The metal layer includes a first section, a second section connected to the first section, a third section, and a fourth section connected to the third section. The first section is positioned on a portion of the first tiered sidewall between the second section and the top surface of the dielectric layer. The third section is positioned on a portion of the second tiered sidewall between the fourth section and the top surface of the dielectric layer. The first section is coplanar with the third section, and the first section and the third section have a first width. The second section is coplanar with the fourth section, and the second section and the fourth section have a second width.

In an embodiment of the invention, a structure for a high-electron-mobility transistor is provided. The structure comprises a gate and a gate electrode including a metal layer. The metal layer includes a bottom section on the gate and a plurality of side sections coupled to the bottom section. The side sections intersect at a plurality of corners.

In an embodiment of the invention, a method comprises forming an opening in a dielectric layer. The dielectric layer includes a top surface, and the opening includes a first tiered sidewall and a second tiered sidewall opposite to the first tiered sidewall. The method further comprises forming a field plate including a metal layer inside the opening in the dielectric layer. The metal layer includes a first section, a second section connected to the first section, a third section, and a fourth section connected to the third section, the first section is positioned on a first portion of the first tiered sidewall between the second section and the top surface of the dielectric layer, the third section is positioned on a first portion of the second tiered sidewall between the fourth section and the top surface of the dielectric layer, the first section is coplanar with the third section, the first section and the third section having a first width, the second section is coplanar with the fourth section, and the second section and the fourth section having a second width.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a structure at an initial fabrication stage of a processing method in accordance with embodiments of the invention.

FIG. 2 is a cross-sectional view of the structure at a fabrication stage subsequent to FIG. 1.

FIG. 3 is a cross-sectional view of the structure at a fabrication stage subsequent to FIG. 2.

FIG. 4 is a cross-sectional view of the structure at a fabrication stage subsequent to FIG. 3.

FIG. 5 is a cross-sectional view of the structure at a fabrication stage subsequent to FIG. 4.

FIG. 6 is a cross-sectional view of the structure at a fabrication stage of a processing method in accordance with embodiments of the invention.

FIG. 7 is a cross-sectional view of the structure at a fabrication stage subsequent to FIG. 6.

FIG. 8 is a cross-sectional view of a structure in accordance with alternative embodiments.

FIG. 9 is a cross-sectional view of a structure in accordance with alternative embodiments.

### DETAILED DESCRIPTION

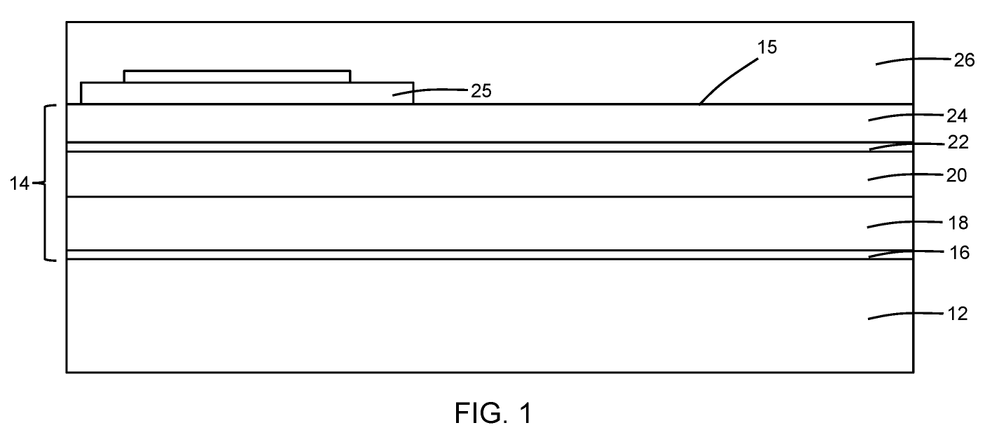

With reference to FIG. 1 and in accordance with embodiments of the invention, a structure 10 may include a layer stack 14 that is formed on a top surface of a substrate 12. The substrate 12 may be comprised of a single-crystal semiconductor material, such as single-crystal silicon. In an embodiment, the substrate 12 may be a bulk substrate that contains a single-crystal semiconductor material, such as single-crystal silicon. In an embodiment, the single-crystal semiconductor material of the substrate 12 may have a diamond crystal lattice structure with a <111> crystal orientation. The substrate 12 may be doped to have, for example, p-type conductivity.

The layer stack 14 may include a seed layer 16, a buffer layer 18, a channel layer 20, a spacer layer 22, and a barrier layer 24 each comprised of one or more compound semiconductor materials. The layers 16, 18, 20, 22, 24 may be serially formed using an epitaxial growth process to form the layer stack 14. Each of the layers 16, 18, 20, 22, 24 of the layer stack 14 may have a crystal lattice structure that is single crystal or, alternatively, a crystal lattice structure that is substantially single crystal with varying levels of crystalline defectivity present. The layer stack 14 may have a thickness, for example, on the order of five (5) micrometers.

The seed layer 16, which provides a thin nucleation layer for the growth of the buffer layer 18, may be comprised of, for example, aluminum nitride. The buffer layer 18 may be comprised of one or more binary or ternary III-V compound semiconductor materials, such as aluminum gallium nitride, gallium nitride, aluminum nitride, or a layered combination of these materials. The buffer layer 18 is tailored in terms of material composition, doping, layering, and/or layer thickness to accommodate lattice mismatch, thermal property differences, and mechanical property differences between the material of the substrate 12 and the material of the channel layer 20. The channel layer 20, which is positioned between the buffer layer 18 and the spacer layer 22, may be comprised of a binary III-V compound semiconductor material, such as gallium nitride. The channel layer 20 may include a sublayer comprised of undoped gallium nitride adjacent to the spacer layer 22 and a sublayer comprised of doped gallium nitride adjacent to the buffer layer 18. The spacer layer 22, which is thin and is positioned between the channel layer 20 and the barrier layer 24, may be comprised of a binary III-V compound semiconductor material, such as aluminum nitride. The material of the spacer layer 22 may be characterized by a higher electrical resistivity than either the material of the channel layer 20 or the material of the barrier layer 24. The barrier layer 24, which is positioned on the spacer layer 22, may contain a ternary III-V compound semiconductor, such as aluminum gallium nitride.

A gate 25 may be positioned on the barrier layer 24. The gate 25 may include a lower layer comprised of a doped III-V compound semiconductor material, such as gallium nitride containing a concentration of a p-type dopant, and an upper layer comprised of a Schottky metal, such as titanium nitride. The doped III-V compound semiconductor material may have a crystal structure that is either single crystal or substantially single crystal, and the doped III-V compound semiconductor material may be deposited by an epitaxial growth process and patterned by lithography and etching processes.

A dielectric layer 26 may be formed that overlies a top surface 15 of the layer stack 14. The dielectric layer 26 may be comprised of a dielectric material, such as silicon oxide (e.g., silicon dioxide), that is an electrical insulator. In an embodiment, the dielectric layer 26 may be comprised of a single layer of the dielectric material. The top surface 15 of the layer stack 14 may represent a horizontal plane in a representative frame of reference.

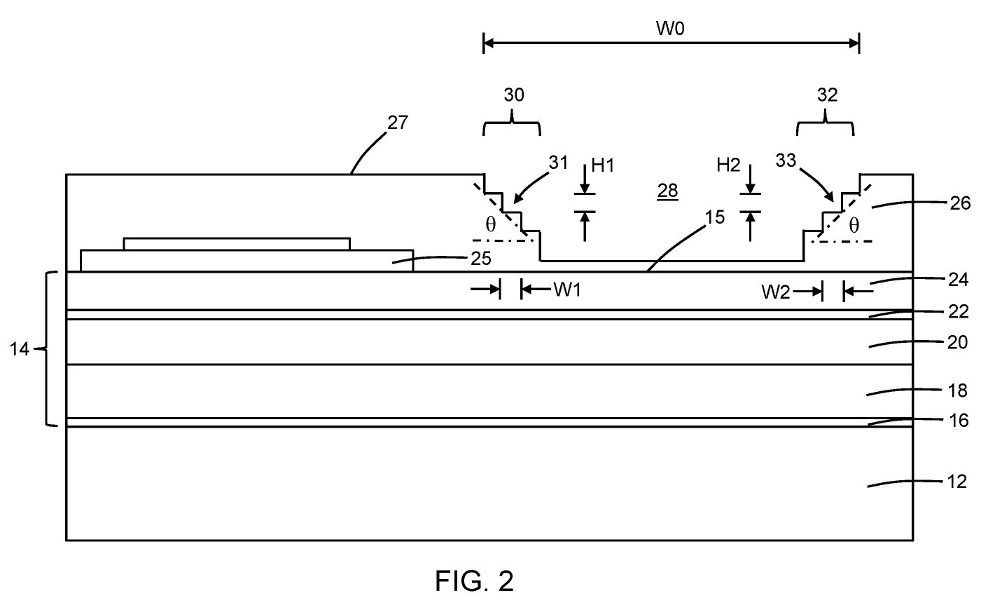

With reference to FIG. 2 in which like reference numerals refer to like features in FIG. 1 and at a subsequent fabrication stage, the dielectric layer 26 may be patterned by lithography and etching processes to form an opening 28 that is arranged adjacent to the gate 25. To that end, an etch mask may be formed by a lithography process over the dielectric layer 26. The etch mask may include a layer of photoresist applied by a spin-coating process, pre-baked, exposed to light projected through a photomask, baked after exposure, and developed with a chemical developer to define an opening in the photoresist at the location for the opening 28. A series of photoresist pullback and depth-controlled etching processes may be used to form the opening 28 at the location of the opening in the photoresist. The photoresist pullback is self-aligned and sub-lithographic because only a single masking step is required. The etch mask may be stripped by, for example, ashing after forming the opening 28.

The opening 28 in the dielectric layer 26 has a tiered sidewall 30 and a tiered sidewall 32 that is opposite from the tiered sidewall 30. The tiered sidewalls 30, 32, which extend in a vertical direction from a top surface 27 of the dielectric layer 26 toward the top surface 15 of the layer stack 14, cooperate to progressively widen the opening 28 with increasing distance from the layer stack 14. In that regard, the opening 28 may have a width dimension W0 that increases with increasing distance from the top surface 15 of the layer stack 14 or, equivalently, decreases with increasing distance from the top surface 27 of the dielectric layer 26. The width dimension W0 may have a maximum value at the top surface 27 of the dielectric layer 26 and a minimum value adjacent to the top surface 15 of the layer stack 14.

The tiered sidewall 30 includes multiple steps or tiers in the form of corners 31 that are connected to provide the tiered sidewall 30 with a series of connected ledges. The corners 31, which include interior corners and exterior corners, are spaced in a vertical direction between the interior corner of the tiered sidewall 30 at the top surface 15 of the layer stack 14 and the exterior corner of the tiered sidewall 30 at the top surface 27 of the dielectric layer 26. The corners 31 represent stepped transitions having a height dimension H1. In an embodiment, the stepped transitions represented by the corners 31 may have equal height dimensions H1. In an alternative embodiment, the stepped transitions represented by two or more of the corners 31 may have unequal height dimensions H1.

The tiered sidewall 32 includes multiple steps or tiers in the form of corners 33 that are connected to provide the tiered sidewall 32 with a series of connected ledges. The corners 33, which include interior corners and exterior corners, are spaced in a vertical direction between the interior corner of the tiered sidewall 32 at the top surface 15 of the layer stack 14 and the exterior corner of the tiered sidewall 32 at the top surface 27 of the dielectric layer 26. The corners 33 represent stepped transitions having a height dimension H2. In an embodiment, the stepped transitions represented by the corners 33 may have equal height dimensions H2. In an alternative embodiment, the stepped transitions represented by the corners 33 may have unequal height dimensions H2. In an alternative embodiment, the stepped transitions represented by the corners 33 may have a combination of equal and unequal height dimensions H2. The sum of the height dimensions H1 and the sum of the height dimensions H2 may each be equal to the depth of the opening 28 relative to the top surface 27 of the dielectric layer 26.

Each corner 31 has a horizontal surface, which may be planar, that is either coplanar or substantially coplanar relative to the top surface 15 of the layer stack 14. Each corner 33 has a horizontal surface, which may be planar, that is either coplanar or substantially coplanar relative to the top surface 15 of the layer stack 14. The horizontal surfaces of the corners 31 of the tiered sidewall 30 and the horizontal surfaces of the corners 33 of the tiered sidewall 32 are positioned in different levels (i.e., elevations) relative to the top surface 15 of the layer stack 14. In an embodiment, the corners 31 of the tiered sidewall 30 and the corners 33 of the tiered sidewall 32 may have a symmetrical arrangement. The number of corners 31 of the tiered sidewall 30 may be equal to the number of corners 33 of the tiered sidewall 32.

The horizontal surfaces of the corners 31 have a width dimension W1, and the horizontal surfaces of the corners 31 have a width dimension W2. In an embodiment, the horizontal surface of each corner 31 may be coplanar with the horizontal surface of one of the corners 33, and the width dimension W1 and the width dimension W2 may be equal for these coplanar horizontal surfaces. The coplanar horizontal surfaces and the equal width dimensions W1, W2 is attributable to the manner in which the opening 28 is formed. In an embodiment, the horizontal surfaces of the corners 31 have unequal width dimensions W1. In an embodiment, the horizontal surfaces of the corners 31 have equal width dimensions W1. In an embodiment, the horizontal surfaces of the corners 33 have unequal width dimensions W2. In an embodiment, the horizontal surfaces of the corners 33 have equal width dimensions W2. The width dimensions W1 of the horizontal surfaces of the corners 31 and the width dimensions W2 of the horizontal surfaces of the corners 33 contribute to the incremental increase in the width dimension W0 with increasing distance from the top surface 15 of the layer stack 14.

The tiered sidewall 30 and the tiered sidewall 32 may have effective slopes, as indicated by the dot-dashed lines that intersect the interior corners 31, 33 in FIG. 2. In an embodiment, the tiered sidewall 30 and the tiered sidewall 32 may be inclined by slopes with equal effective angles θ relative to the horizontal plane of the top surface 15 of the layer stack 14. The height dimensions H1, H2 are equal for horizontal surfaces of the corners 31, 33 that are coplanar.

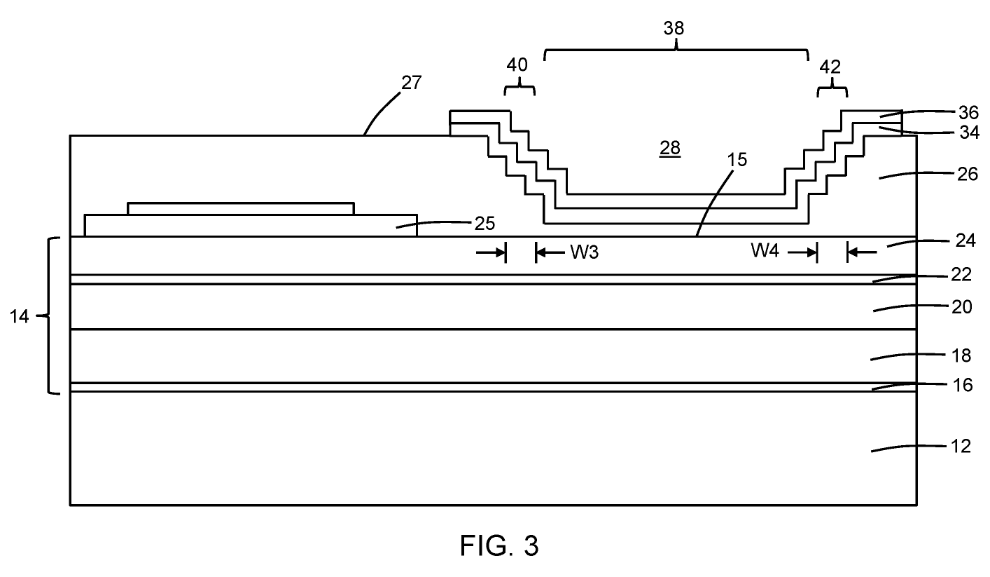

With reference to FIG. 3 in which like reference numerals refer to like features in FIG. 2 and at a subsequent fabrication stage, a layer 34 and a dielectric layer 36 may be formed that coat the tiered sidewalls 30, 32 and the bottom of the opening 28. The layer 34 may be positioned between the dielectric layer 36 and the dielectric material of the dielectric layer 26. The layer 34 may be comprised of a metal, such as titanium nitride or tantalum nitride. The dielectric layer 36 may be comprised of a dielectric material, such as silicon nitride. The layer 34 and the dielectric layer 36 may be conformal layers that adapt to the stepped shapes of the tiered sidewalls 30, 32 with a conformal thickness that is constant (i.e., uniform) over the surfaces of the opening 28 and the top surface 27 of the dielectric layer 26. The layers 34, 36 may be patterned by lithography and etching processes.

The layer 34 includes a section 38 that is positioned adjacent to the top surface 15 of the layer stack 14 between the tiered sidewalls 30, 32. The layer 34 includes sections 40 that are positioned on and overlie the corners 31 of the tiered sidewall 30. An uppermost section 40 is positioned on the top surface 27 of the dielectric layer 26 adjacent to the tiered sidewall 30. The layer 34 includes sections 42 that are positioned on and overlie the corners 33 of the tiered sidewall 32. An uppermost section 42 is positioned on the top surface 27 of the dielectric layer 26 adjacent to the tiered sidewall 32. The dielectric layer 36 may also have a conformal thickness with sections that respectively overlie and overlap with the sections 38, 40, 42 of the layer 34.

Adjacent pairs of the sections 40 of the layer 34 may be connected by vertical sections to establish corners in the layer 34. The lowermost section 40 is connected by a vertical section to one side edge portion of the section 38. The uppermost section 40 is positioned to overlie and overlap with the top surface 27 of the dielectric layer 26. The sections 40 have a width dimension W3. In an embodiment, the sections 40 between the uppermost section 40 and the section 38 may have unequal width dimensions W3. In an embodiment, the sections 40 between the uppermost section 40 and the section 38 may have equal width dimensions W3. The uppermost section 40 may have a width dimension W3 that differs from the width dimensions W3 of the sections 40 arranged in a vertical direction between the uppermost section 40 and the section 38.

Adjacent pairs of the sections 42 of the layer 34 may be connected by vertical sections to establish corners in the layer 34. A lowermost section 42 is connected by a vertical section to one side edge portion of the section 38. The uppermost section 42 is positioned to overlie and overlap with the top surface 27 of the dielectric layer 26. The sections 42 have a width dimension W4. The uppermost section 42 may have a width dimension W4 that is greater than or equal to the width dimension W4 of the sections 42 arranged in a vertical direction between the uppermost section 42 and the section 38. In an embodiment, the sections 42 between the uppermost section 42 and the section 38 may have equal width dimensions W4. In an embodiment, the sections 42 between the uppermost section 42 and the section 38 may have unequal width dimensions W4.

Each section 42 may be coplanar with one of the sections 40. In that regard, each section 42 may have a horizontal top surface that is coplanar with the horizontal top surface of one of the sections 40, as well as coplanar horizontal bottom surfaces positioned on the horizontal surfaces of the corners 31, 33. The width dimensions W3, W4 may be equal for each pair of coplanar sections 40, 42, which is attributable to the manner in which the opening 28 is formed.

The sections 38, 40, 42 of the layer 34 may represent a field plate of a high-electron-mobility transistor included in the structure 10. The field plate represented by the sections 38, 40, 42 of the layer 34 is positioned adjacent to the gate 25. Respective pairs of the sections 40 and the sections 42 are self-aligned in a horizontal direction by the pairs of coplanar horizontal top surfaces of the corners 31, 33 of the tiered sidewalls 30, 32. The sections 40 on the tiered sidewall 30 and the sections 42 on the tiered sidewall 32 may have a symmetrical arrangement (e.g., mirror symmetry) inside the opening 28.

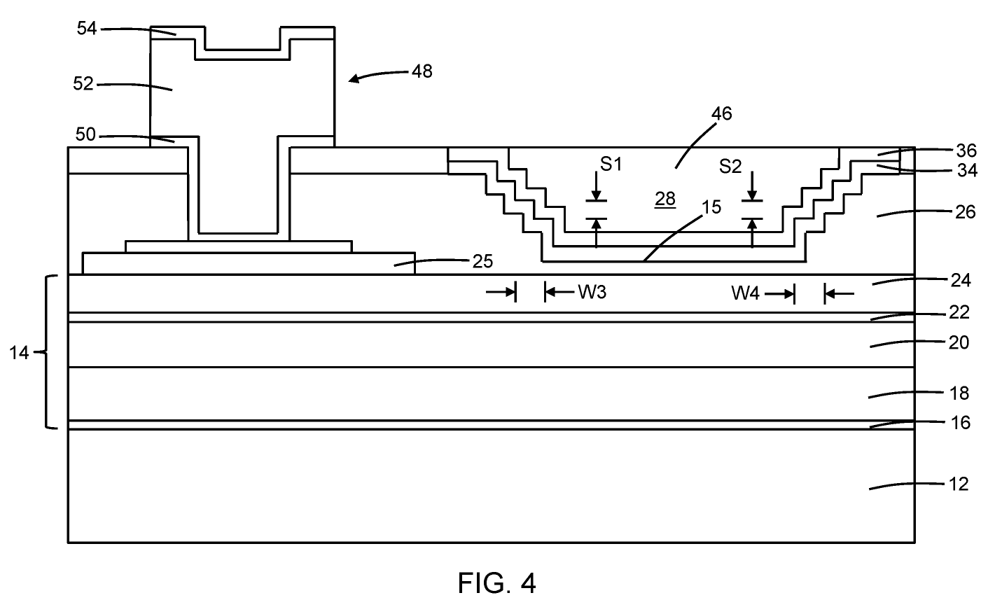

With reference to FIG. 4 in which like reference numerals refer to like features in FIG. 3 and at a subsequent fabrication stage, a dielectric layer 46 may be deposited and a gate electrode 48 may be formed on the gate 25. A portion of the dielectric layer 46 may fill the remaining space inside the opening 28 that is not filled by the layers 34, 36. The gate electrode 48 includes a lower portion that extends through the dielectric layer 26 and the dielectric layer 46 to the gate 25, as well as an upper portion that overlies the dielectric layer 46. The gate electrode 48 may include multiple layers 50, 52, 54 in which the layer 52 is arranged between the layer 50 and the layer 54. In an embodiment, the layer 50 and the layer 54 may be comprised of a metal, such as titanium nitride, and the layer 52 may be comprised of a metal, such as aluminum.

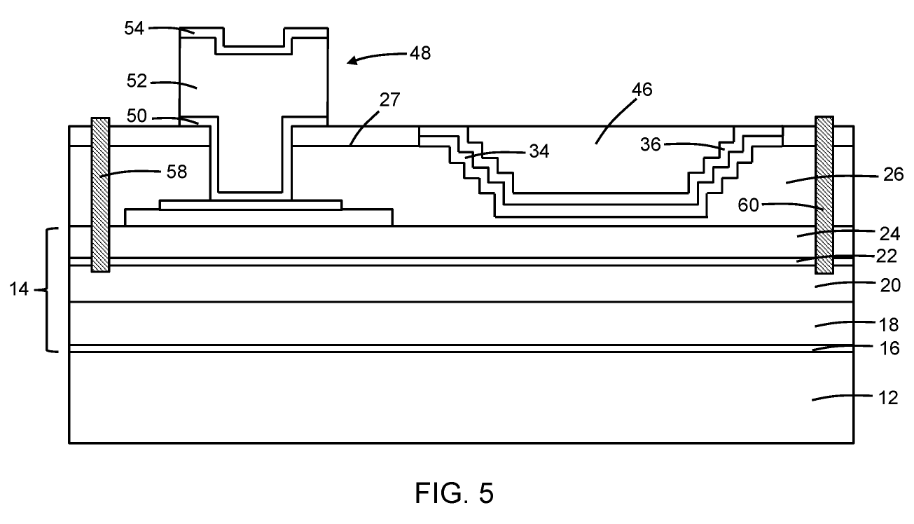

With reference to FIG. 5 in which like reference numerals refer to like features in FIG. 4 and at a subsequent fabrication stage, an ohmic contact 58 and an ohmic contact 60 may be formed. The gate 25 is positioned in a lateral direction between the ohmic contact 58 and the ohmic contact 60. The field plate represented by the sections 38, 40, 42 of the layer 34 is positioned in a lateral direction between the gate 25 and the ohmic contact 60. In an embodiment, the ohmic contacts 58, 60 may contain a mixture of polycrystalline grains that are comprised of aluminum, titanium, and silicon and polycrystalline grains that are comprised of aluminum.

In an embodiment, the ohmic contact 58 and the ohmic contact 60 may represent respective terminals of the high-electron-mobility transistor. In an embodiment, the ohmic contact 58 may represent a source terminal of the high-electron-mobility transistor and the ohmic contact 60 may represent a drain terminal of the high-electron-mobility transistor. A channel is defined between the ohmic contacts 58, 60 in which carrier flow in the two-dimensional electron gas is controlled by the gate 25.

Embodiments of the invention provide a field plate, which is represented by the sections 38, 40, 42 of the layer 34, that may function to reshape the electric field distribution in the channel between the ohmic contacts 58, 60. The field may also function to reduce the peak value for the electric field on the side of the gate 25 adjacent to the ohmic contact 60. The field plate may increase the breakdown voltage of the high-electron-mobility transistor and may also reduce the high-field trapping effect inherent to a high-electron-mobility transistor.

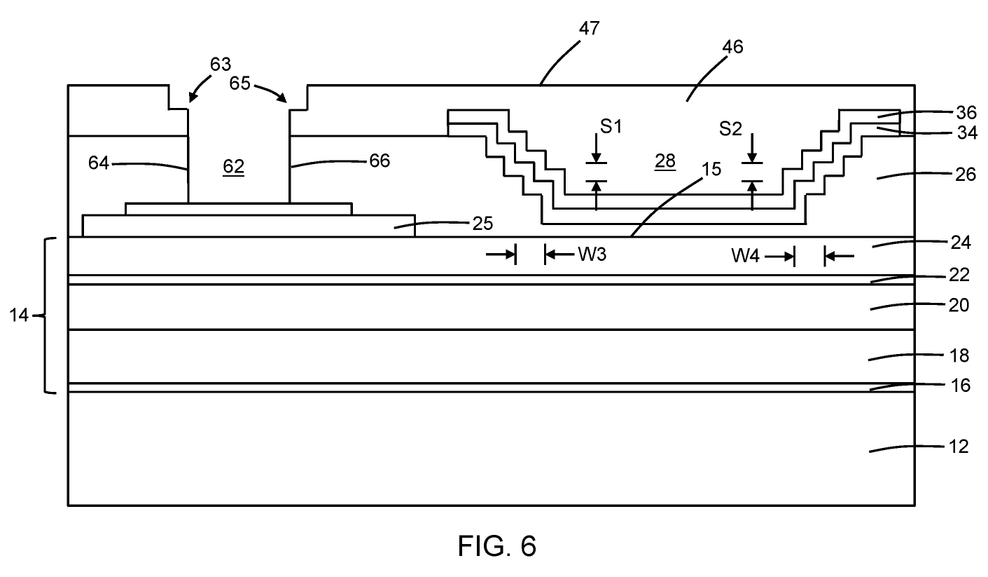

With reference to FIG. 6 and in accordance with alternative embodiments, the dielectric layer 26 and the dielectric layer 46 may be patterned by lithography and etching processes to define an opening 62 that exposed a portion of the gate 25. The processes forming the opening 62 are similar to the processed forming the opening 28 such that the opening 62 includes a tiered sidewall 64 and a tiered sidewall 66 that is opposite from the tiered sidewall 64. The tiered sidewall 64 includes an interior corner and an exterior corner, collectively indicated by reference numeral 63, in addition to an interior corner at the bottom of the opening 62 and an exterior corner at the top of the opening 62. The tiered sidewall 66 includes an interior corner and an exterior corner, collectively indicated by reference numeral 65, in addition to an interior corner at the bottom of the opening 62 and an exterior corner at the top of the opening 62. The tiered sidewalls 64, 66 extend in a vertical direction from a top surface 47 of the dielectric layer 46 to the portion of the gate 25.

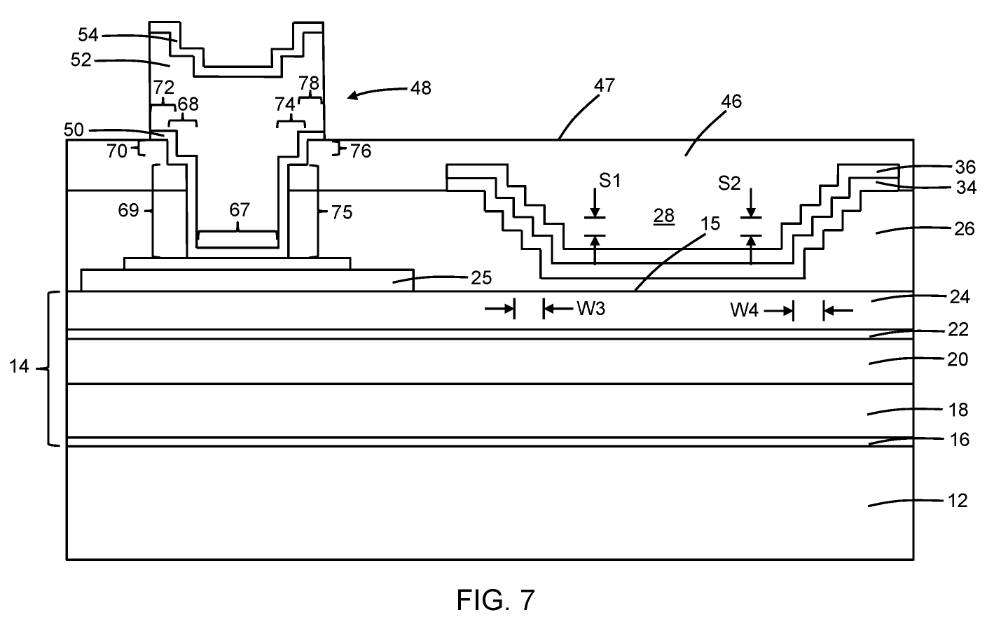

With reference to FIG. 7 in which like reference numerals refer to like features in FIG. 6 and at a subsequent fabrication stage, the layer 50 of the gate electrode 48 may be formed on the tiered sidewalls 64, 66 of the opening 62 in the dielectric layer 46. In that regard, the layer 50 may be a conformal layer that adapts to the stepped shapes of the tiered sidewalls 64, 66 with a constant (i.e., uniform) thickness. The layer 52 and the layer 54 may also acquire the topography of the tiered sidewalls 64, 66.

The layer 50 includes a bottom section 67 that is positioned on a portion of the gate 25 between the tiered sidewall 64 and the tiered sidewall 66. In an embodiment, the bottom section 67 may adjoin the portion of the gate 25. The layer 50 includes a side section 68 on a planar horizontal surface of the tiered sidewall 64, a side section 70 on a vertical surface of the tiered sidewall 64, and a side section 72 on the top surface 47 of the dielectric layer 46. The side section 70 extends in a vertical direction between the side section 68 and the side section 72. The layer 50 includes a side section 69 on a vertical surface of the tiered sidewall 64 that connects the side section 68 to an edge portion of the bottom section 67. The layer 50 includes a side section 74 on a planar horizontal surface of the tiered sidewall 66, a side section 76 on a vertical surface of the tiered sidewall 66, and a side section 78 on the top surface 47 of the dielectric layer 46. The side section 76 extends in a vertical direction between the side section 74 and the side section 78. The layer 50 includes a side section 75 on a portion of the tiered sidewall 66 that connects the side section 74 to an edge portion of the bottom section 67.

The bottom section 67 may be oriented in a horizontal plane relative to the top surface 15 of the layer stack 14. The side section 68 and the side section 74 may be oriented in a horizontal plane relative to the top surface 15 of the layer stack 14 and therefore in a horizontal plane that is parallel to the horizontal plane of the bottom section 67. The side section 68 may have top and bottom surfaces that are coplanar with the top and bottom surfaces of the side section 74. The side section 70 may have horizontal top and bottom surfaces that are coplanar with the horizontal top and bottom surfaces of the side section 76. The side section 68 and the side section 72 introduce a step in the layer 50 that is absent in a conventional gate electrode, and the side section 74 and the side section 78 introduce another step in the layer 50 that is absent in a conventional gate electrode. In an embodiment, the width of the side section 68 may be equal to the width of the side section 74. The equal widths are attributable to the method by which the opening 62 is formed.

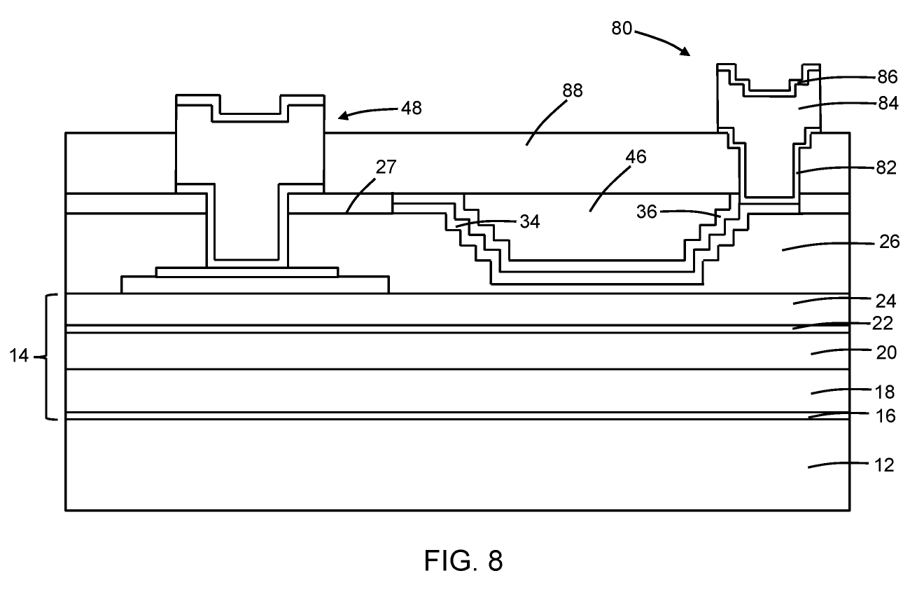

With reference to FIG. 8 and in accordance with alternative embodiments, a field plate 80 may include a layer 82, a layer 84, and a layer 86. The field plate 80 may be structurally similar, or identical, to the gate electrode 48 (FIG. 7). In that regard, the field plate 80 may be formed using an opening in a dielectric layer 88, and the layer 82 may include horizontal side sections disposed on portions of opposite tiered sidewalls of the opening in the dielectric layer 88. A bottom section of the layer 82 is coupled to the uppermost section 42 of the layer 34. The layer 82 and the layer 86 may be comprised of a metal, such as titanium nitride, and the layer 84 may be comprised of a metal, such as aluminum.

The horizontal side sections of the layer 82 on the portions of the opposite tiered sidewalls may be coplanar. The horizontal side sections of the layer 82 contribute to forming steps in the layer 50 that is absent in a conventional field plate. In an embodiment, the widths of the coplanar horizontal side sections may be equal. The equal widths are attributable to the method by which the opening is formed in the dielectric layer 88.

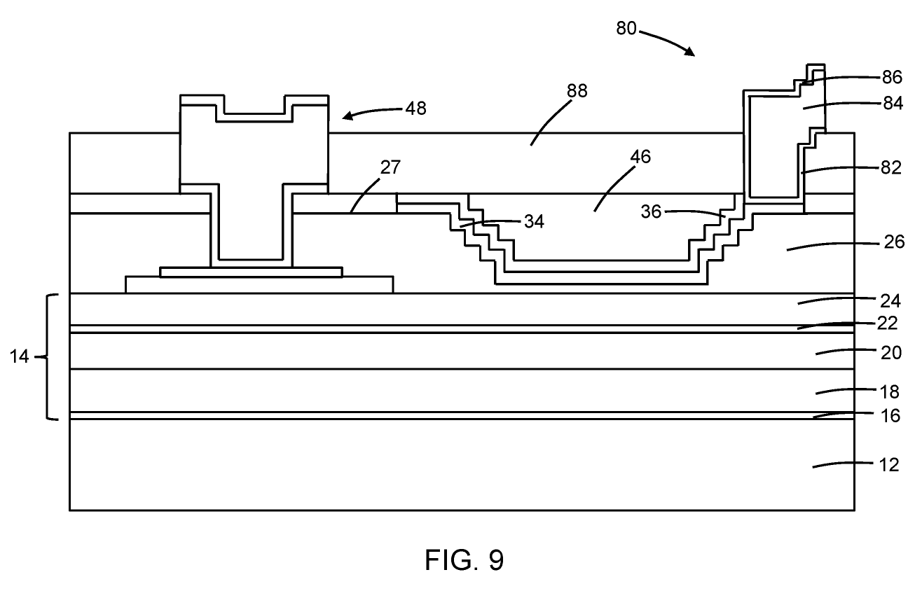

With reference to FIG. 9 and in accordance with alternative embodiments, only one of the sidewalls of the opening in the dielectric layer 88 may be tiered. For example, the sidewall of the opening in the dielectric layer 88 that is closest to the gate 25 may lack tiering.

In an alternative embodiment, the field plate of FIG. 5 may include a sidewall that lacks tiers. For example, the sidewall closest to the gate 25 may lack tiering such that only the sidewall closest to the ohmic contact 60 includes a tiered sidewall.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. Different features may “overlap” if a feature extends over, and covers a part of, another feature. A feature may “overlie” another feature if a feature is positioned “over” another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first dielectric layer including a top surface and an opening, the opening including a first tiered sidewall and a second tiered sidewall opposite to the first tiered sidewall; and
a first field plate including a first metal layer inside the opening in the first dielectric layer, the first metal layer including a first section, a second section connected to the first section, a third section, and a fourth section connected to the third section, the first section positioned on a first portion of the first tiered sidewall between the second section and the top surface of the first dielectric layer, the third section positioned on a first portion of the second tiered sidewall between the fourth section and the top surface of the first dielectric layer, the first section being coplanar with the third section, the first section and the third section having a first width, the second section being coplanar with the fourth section, and the second section and the fourth section having a second width.

2. The structure of claim 1 further comprising:
a substrate; and
a layer stack on the substrate, the layer stack including a top surface and a plurality of III-V compound semiconductor layers, the plurality of III-V compound semiconductor layers arranged between the substrate and the top surface of the layer stack,
wherein the first dielectric layer is positioned on the top surface of the layer stack.

3. The structure of claim 2 wherein the first tiered sidewall is sloped at a first angle relative to the top surface of the layer stack, the second tiered sidewall is sloped at a second angle relative to the top surface of the layer stack, and the first angle is equal to the second angle.

4. The structure of claim 1 wherein further comprising:
a gate; and
a first ohmic contact,
wherein the first field plate is arranged in a lateral direction between the gate and the first ohmic contact.

5. The structure of claim 4 further comprising:
a second ohmic contact,
wherein the gate is arranged in the lateral direction between the first field plate and the second ohmic contact.

6. The structure of claim 1 wherein the first metal layer comprises titanium nitride or tantalum nitride, and the first dielectric layer comprises silicon oxide.

7. The structure of claim 1 wherein the first metal layer includes a first step transitioning from the first section of the first metal layer to the second section of the first metal layer, and the first metal layer includes a second step transitioning from the third section of the first metal layer to the fourth section of the first metal layer.

8. The structure of claim 1 wherein the second section of the first metal layer is positioned on a second portion of the first tiered sidewall, and the fourth section of the first metal layer is positioned on a second portion of the second tiered sidewall.

9. The structure of claim 1 wherein the first metal layer includes a fifth section extending from the second section and the fourth section, and the fifth section is positioned at a bottom of the opening.

10. The structure of claim 1 further comprising:
a second dielectric layer on the first dielectric layer, the second dielectric layer including a portion inside the opening.

11. The structure of claim 10 wherein the first section of the first metal layer and the second section of the first metal layer are positioned between the portion of the second dielectric layer and the first tiered sidewall of the first dielectric layer, and the third section of the first metal layer and the fourth section of the first metal layer are positioned between the portion of the second dielectric layer and the second tiered sidewall of the first dielectric layer.

12. The structure of claim 1 wherein the first metal layer has a conformal thickness on the first tiered sidewall and the second tiered sidewall.

13. The structure of claim 1 further comprising:
a second field plate coupled to the first field plate.

14. The structure of claim 13 wherein the second field plate includes a second metal layer, the second metal layer including a bottom section coupled to a portion of the first metal layer and a plurality of first side sections coupled to the bottom section, and the first plurality of side sections intersect at a first plurality of corners.

15. The structure of claim 14 wherein the second metal layer includes a second plurality of side sections coupled to the bottom section, and the second plurality of side sections intersect at a second plurality of corners.

16. The structure of claim 1 wherein the second width that is equal to the first width.

17. A structure for a high-electron-mobility transistor, the structure comprising:
a gate; and
a gate electrode including a metal layer, the metal layer including a bottom section on the gate and a first plurality of side sections coupled to the bottom section, and the first plurality of side sections intersecting at a first plurality of corners.

18. The structure of claim 17 wherein the metal layer includes a second plurality of side sections coupled to the bottom section, the second plurality of side sections intersect at a second plurality of corners, and the bottom section connects one of the first plurality of side sections to one of the second plurality of side sections.

19. The structure of claim 17 further comprising:
a substrate; and
a layer stack on the substrate, the layer stack including a top surface and a plurality of III-V compound semiconductor layers arranged between the substrate and the top surface
wherein the gate is positioned on the top surface of the layer stack.

20. A method comprising:
forming an opening in a dielectric layer, wherein the dielectric layer includes a top surface, and the opening includes a first tiered sidewall and a second tiered sidewall opposite to the first tiered sidewall; and
forming a field plate including a metal layer inside the opening in the dielectric layer, wherein the metal layer includes a first section, a second section connected to the first section, a third section, and a fourth section connected to the third section, the first section is positioned on a first portion of the first tiered sidewall between the second section and the top surface of the dielectric layer, the third section is positioned on a first portion of the second tiered sidewall between the fourth section and the top surface of the dielectric layer, the first section is coplanar with the third section, the first section and the third section having a first width, the second section is coplanar with the fourth section, and the second section and the fourth section having a second width that is equal to the first width.
